(19) United States
(12) Patent Application Publication
(10) Pub. No.: US 2026/0331060 A1
(43) Pub. Date: Oct. 22, 2026

(54) DISPLAY PANEL AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Qing HE, Beijing (CN); Mengqi WANG, Beijing (CN); Ziyang YU, Beijing (CN); Qingqing YAN, Beijing (CN); Fang FANG, Beijing (CN); Haijun QIU, Beijing (CN); Ming HU, Beijing (CN); Zhiliang JIANG, Beijing (CN)

(21) Appl. No.: 18/994,023

(22) PCT Filed: Sep. 27, 2023
(86) PCT No.: PCT/CN2023/122072

§ 371 Date: Jan. 13, 2025

(51) Int. Cl. G09G 3/3266

(52) U.S. Cl. CPC G09G 3/3266; G09G 2300/0408; G09G 2300/0426

(57) ABSTRACT

A display panel and a display device are provided. The display panel further includes a drive module and a drive integrated circuit (IC); the drive IC is configured to provide drive control signals for drive circuits via gate on array (GOA) signal lines; the GOA signal lines include first GOA signal lines arranged between a display area and the drive IC; at least part of the drive circuits included in the drive module are arranged in the display area; the at least part of the drive circuits arranged in the display area and included in the drive module are electrically connected to the drive IC via the first GOA signal lines, for receiving the drive control signals from the drive IC; the first GOA signal lines extend in a first direction; the display panel further includes data lines.

### CROSS REFERENCE OF RELATED APPLICATION

This application is the U.S. national phase of PCT Application PCT/CN2023/122072 filed on Sep. 27, 2023, the disclosures of which are incorporated in their entirety by reference herein for all purposes.

### TECHNICAL FIELD

The present disclosure relates to the field of display technology, and in particular, to a display panel and a display device.

### BACKGROUND

In recent years, the market and customers have presented numerous demands for the appearance of displays, with a larger screen-to-body ratio and a narrower bezel being among the most common and urgent requirements. The display with an extremely narrow bezel is not only aesthetically pleasing but also more practical. Currently, there are various methods to reduce the bezel width. For instance, technologies such as gate-in-panel (GIP) and fan-out-in-panel (FIP) have been gradually implemented in products.

Generally, a gate on array (GOA, a gate drive circuit arranged on an array substrate) module and signal lines thereof are placed at left and right bezels and corners outside a display area of a display panel. A drive integrated circuit (IC) and a flexible printed circuit (FPC) located at a lower pad area input signals to the GOA module through complex winding. The GIP technology compresses the size of pixel circuits and positions at least part of the GOA circuit beneath the anode layer of the display area, enabling a significant reduction in bezel width. Challenges arise in efficiently and conveniently routing signal lines to connect the IC and FPC in the lower pad area when the GOA circuit is located near the center of the display area. Simultaneously, clients also demand that the size of the lower pad area should be minimized to free up more space for other components of the entire device and prevent interference.

### SUMMARY

In one aspect, the embodiments of the present disclosure provide a display panel including a display area and pixel circuits arranged in the display area, where the display panel further includes a drive module and a drive IC; the drive module includes a plurality of drive circuits, and the drive circuits are configured to provide drive signals for the pixel circuits; the drive IC is configured to provide drive control signals for the drive circuits via GOA signal lines; the GOA signal lines include first GOA signal lines arranged between the display area and the drive IC.

At least part of the drive circuits included in the drive module are arranged in the display area.

The at least part of the drive circuits arranged in the display area and included in the drive module are electrically connected to the drive IC via the first GOA signal lines, for receiving the drive control signals from the drive IC.

The first GOA signal lines extend in a first direction.

The display panel further includes data lines, and the data lines are configured to provide data voltage for the pixel circuits; the data lines extend in substantially a same direction as the first direction.

Optionally, the at least part of the drive circuits included in the drive module are arranged in the middle of the display area, and the at least part of the drive circuits are aligned in the first direction.

Optionally, the at least part of the drive circuits included in the drive module are first drive circuits.

A plurality of drive circuits other than the first drive circuits included in the drive module are second drive circuits.

The drive IC and the first GOA signal lines are arranged on a first side of the display area.

A plurality of second drive circuits included in the drive circuits are arranged on a second side and/or a third side of the display area; the second side and the third side are opposite sides.

Optionally, the GOA signal lines further include second GOA signal lines extending in a second direction; the first direction intersects the second direction.

The first GOA signal lines are electrically connected to the second GOA signal lines.

The second GOA signal lines are electrically connected to the drive IC.

The second GOA signal lines are configured to receive and pass the drive control signals from the drive IC.

Optionally, a fan-out area, a bending area, a box-forming testing area, and an area where the drive IC is arranged are sequentially arranged at the first side of the display area in a direction away from the display area.

The second GOA signal lines are arranged between the bending area and the box-forming testing area.

Optionally, at least part of the first GOA signal lines are directly electrically connected to the drive IC, for receiving the drive control signals from the drive IC.

Optionally, the GOA signal lines further include second GOA signal lines extending in a second direction; the first direction intersects the second direction.

Part of the first GOA signal lines are electrically connected to the second GOA signal lines.

The second GOA signal lines are directly electrically connected to the second drive circuits, for providing the drive control signals to the second drive circuits.

Optionally, the first GOA signal lines are electrically connected to a port located in the middle of the drive IC.

Optionally, the GOA signal lines further include second GOA signal lines, the second GOA signal lines extending in a second direction; the first direction intersects the second direction.

The first GOA signal lines are directly connected to the second GOA signal lines.

A fan-out area, a bending area, a box-forming testing area, and an area where the drive IC is arranged are sequentially arranged at the first side of the display area in a direction away from the display area.

The second GOA signal lines are arranged in the fan-out area.

The second GOA signal lines are electrically connected to the drive IC.

Optionally, the plurality of second drive circuits are arranged on the second side and the third side of the display area.

A first end portion of the second GOA signal line is electrically connected to a second drive circuit arranged on the second side of the display area and a first port of the drive IC.

A second end portion of the second GOA signal line is electrically connected to a second drive circuit arranged on the third side of the display area and a second port of the drive IC.

Optionally, the plurality of second drive circuits are arranged on the second side of the display area; a first end portion of the second GOA signal line is electrically connected to a second drive circuit arranged on the second side of the display area and a first port of the drive IC.

Alternatively, the plurality of second drive circuits are arranged on the third side of the display area.

A second end portion of the second GOA signal line is electrically connected to a drive circuit arranged on the third side of the display area and a second port of the drive IC.

Optionally, the display panel of at least one embodiment of the present disclosure further includes a circuit board.

The circuit board is arranged on a side of the drive IC away from the display area.

The circuit board is electrically connected to the first drive circuit and the second drive circuit, for providing direct current (DC) voltage signals to the first drive circuit and the second drive circuit.

Optionally, the circuit board is further electrically connected to the drive IC, for providing DC voltage signals to the drive IC.

The drive IC is configured to generate the drive control signals according to the DC voltage signals, and provide the drive control signals to the first drive circuit and the second drive circuit.

Optionally, all the drive circuits included in the drive module are arranged in the display area.

The first GOA signal lines are directly electrically connected to the drive IC, for receiving the drive control signals from the drive IC.

Optionally, the display panel according to at least one embodiment of the present disclosure further includes voltage signal lines.

The voltage signal lines are electrically connected to the drive circuits, for providing DC voltage signals to the drive circuits.

Optionally, the voltage signal lines are electrically connected to the drive IC for providing DC voltage signals to the drive IC.

The drive IC is configured to generate the drive control signals according to the DC voltage signals, and provide the drive control signals to the drive circuits.

Optionally, the display panel of at least one embodiment of the present disclosure further includes a circuit board arranged on the drive IC away from the display area.

The circuit board is electrically connected to the voltage signal lines, for providing the DC voltage signals to the voltage signal lines.

In a second aspect, the embodiments of the present disclosure further provide a display device including the above display panel.

### BRIEF DESCRIPTION OF THE DRAWINGS

FIG. 1A is a structural diagram of a display panel according to at least one embodiment of the present disclosure;

FIG. 1B is a structural diagram of a display panel according to at least one embodiment of the present disclosure;

FIG. 1C is a structural diagram of a display panel according to at least one embodiment of the present disclosure;

FIG. 2 is a diagram of areas of a display panel;

FIG. 3A is a layout diagram of a partial area of a lower pad area of a display panel according to at least one embodiment of the present disclosure;

FIG. 3B is a layout diagram of a first gate metal layer of FIG. 3A;

FIG. 3C is a layout diagram of a second gate metal layer of FIG. 3A;

FIG. 3D is a layout diagram of a first source drain metal layer of FIG. 3A;

FIG. 3E is a layout diagram of a second source drain metal layer of FIG. 3A;

FIG. 4A is a layout diagram of a first gate metal layer in at least one embodiment of the present disclosure;

FIG. 4B is a layout diagram of a second gate metal layer in at least one embodiment of the present disclosure;

FIG. 5A is a structural diagram of a display panel according to at least one embodiment of the present disclosure;

FIG. 5B is a structural diagram of a display panel according to at least one embodiment of the present disclosure;

FIG. 5C is a structural diagram of a display panel according to at least one embodiment of the present disclosure;

FIG. 5D is a structural diagram of a display panel according to at least one embodiment of the present disclosure;

FIG. 5E is a structural diagram of a display panel according to at least one embodiment of the present disclosure;

FIG. 6A is a structural diagram of a display panel according to at least one embodiment of the present disclosure;

FIG. 6B is a structural diagram of a display panel according to at least one embodiment of the present disclosure;

FIG. 6C is a structural diagram of a display panel according to at least one embodiment of the present disclosure;

FIG. 7A is a structural diagram of a display panel according to at least one embodiment of the present disclosure;

FIG. 7B is a structural diagram of a display panel according to at least one embodiment of the present disclosure;

FIG. 7C is a structural diagram of a display panel according to at least one embodiment of the present disclosure;

FIG. 8A is a structural diagram of a display panel according to at least one embodiment of the present disclosure;

FIG. 8B is a structural diagram of a display panel according to at least one embodiment of the present disclosure.

### DETAILED DESCRIPTION

Reference will now be made in detail to the embodiments of the present disclosure, examples of which are illustrated in the accompanying drawings the disclosure are shown. It is to be understood that the embodiments described are merely illustrative of some, but not all, embodiments of the disclosure. Based on the embodiments in the present disclosure, all other embodiments obtained by a person of ordinary skill in the art without inventive effort are within the scope of the present disclosure.

The transistors employed in all embodiments of the present disclosure may be thin film transistors or field effect transistors or other devices having the same characteristics. In embodiments of the present disclosure, to distinguish between two poles of a transistor other than a gate, one of the poles is referred to as a first pole and the other is referred to as a second pole.

In practical operation, when the transistor is a thin film transistor or a field effect transistor, the first pole may be a drain pole, and the second pole may be a source pole; alternatively, the first pole may be a source pole and the second pole may be a drain pole.

The embodiments of the present disclosure provide a display panel including a display area and pixel circuits arranged in the display area, where the display panel further includes a drive module and a drive IC; the drive module includes a plurality of drive circuits, and the drive circuits are configured to provide drive signals for the pixel circuits; the drive IC is configured to provide drive control signals for the drive circuits via GOA signal lines; the GOA signal lines include first GOA signal lines arranged between the display area and the drive IC.

At least part of the drive circuits included in the drive module are arranged in the display area.

The at least part of the drive circuits arranged in the display area and included in the drive module are electrically connected to the drive IC via the first GOA signal lines, for receiving the drive control signals from the drive IC.

The first GOA signal lines extend in a first direction.

The display panel further includes data lines, and the data lines are configured to provide data voltage for the pixel circuits; the data lines extend in substantially a same direction as the first direction.

In specific implementations, the first direction may be a vertical direction, but is not so limited.

In at least one embodiment of the present disclosure, the data lines extending in substantially a same direction as the first direction may mean that:
the data lines extend in a same direction as the first direction; or
the data lines extend in a direction at an angle less than 5 degrees from the first direction.

This is not a limitation.

In the related art, the market and customers place many demands on the appearance of displays, and a narrower bezel is one of the most common and pressing demands. The display with an extremely narrow bezel is not only aesthetically pleasing but also more practical. Currently, there are various methods to reduce the bezel width. In a general case, a GOA (a gate drive circuit arranged on an array substrate) circuit and signal lines thereof are placed at left and right bezels and corners outside an active area (AA) of an organic light-emitting diode (OLED) display, and a drive IC and an FPC located at the lower side of the display panel input signals to the GOA circuit through leads, which is disadvantageous in achieving a narrow lower rounded bezel and a small size of a lower pad area.

Based on the above-mentioned problems, the embodiments of the present disclosure apply GIP technology, arrange at least part of the drive circuit included in the drive module in the display area (in the display area, at least part of the drive circuit included in the drive module is arranged below the anode layer), and electrically connect the at least part of the drive circuit with the drive IC via the first GOA signal line extending along the first direction, to reduce the space occupied by the GOA signal line, and achieve a narrower lower rounded bezel and a smaller size of the lower pad area, thereby not only improving the screen occupation ratio, but also reserving space to provide more solutions for the overall machine design. In at least one embodiment of the present disclosure, at least part of the drive circuit included in the drive module is arranged in the middle of the display area, but not limited thereto; in actual operation, the at least part of the drive circuit may further be located on the left half and/or the right half of the display panel.

The at least part of the drive circuit is arranged in a first direction.

In specific implementations, when the at least part of the circuit is arranged in the middle of the display area, only one drive circuit may be arranged corresponding to each row of pixel circuits, and the drive circuit is electrically connected to the middle of a row of scanning lines to provide scanning signals for the scanning lines, to reduce the number of drive circuits used, and thus reduce the connection lines between the drive circuit and the drive IC.

In at least one embodiment of the present disclosure, the at least part of the drive circuit included in the drive module is a first drive circuit.

A plurality of drive circuits other than the first drive circuits included in the drive module are second drive circuits.

The drive IC and the first GOA signal lines are arranged on a first side of the display area.

A plurality of second drive circuits included in the drive circuits are arranged on a second side and/or a third side of the display area; the second side and the third side are opposite sides.

In specific implementations, a first drive circuit included in the drive module is arranged on the display area, a second drive circuit included in the drive module is arranged on a second side and/or a third side of the display area, and the second side and the third side are two opposite sides; for example, the first side may be a lower side, the second side may be a left side, and the third side may be a right side.

In at least one embodiment of the present disclosure, the first drive circuit may be one of, but is not limited to, a drive circuit for providing an N-type drive signal, a drive circuit for providing a P-type drive signal, and a drive circuit for providing a light emission control signal.

The drive IC can provide a corresponding drive control signal for the first drive circuit and the second drive circuit, for example, the drive control signal can include a clock signal, a start signal, a bezel start signal, etc.

The drive IC can further provide a drive control signal for the first drive circuit and the second drive circuit at the same time, for example, the drive control signal can be a strobe signal; the strobe signal may be used to control the sub-area display.

In at least one embodiment of the present disclosure, the GOA signal line further includes a second GOA signal line extending in a second direction; the first direction intersects the second direction.

The first GOA signal lines are electrically connected to the second GOA signal lines.

The second GOA signal lines are electrically connected to the drive IC.

The second GOA signal lines are configured to receive and pass the drive control signals from the drive IC.

In specific implementations, the GOA signal line may further include a second GOA signal line extending along a second direction, for example, but not limited to, a horizontal direction; a second GOA signal line receives and passes drive control signals from the drive IC.

Optionally, the drive control signal may be, for example, a clock signal, a start signal, etc. for controlling the operation of the drive circuit.

The display panel of at least one embodiment of the present disclosure may further include a circuit board.

The circuit board is arranged on a side of the drive IC away from the display area.

The circuit board is electrically connected to the first drive circuit and the second drive circuit for providing a DC voltage signal to the first drive circuit and the second drive circuit.

In specific implementations, the drive IC and the circuit board may both be arranged at a lower pad area of a display panel, the lower pad area may be arranged at a lower side of the display area, and the circuit board may be arranged at a side of the drive IC away from the display area; the circuit board may be used to provide a DC voltage signal to the first drive circuit and the second drive circuit, which may include, but is not limited to, a high voltage signal, a low voltage signal, for example.

In at least one embodiment of the present disclosure, the circuit board is further electrically connected to the drive IC for providing a DC voltage signal to the drive IC.

The drive IC is configured to generate the drive control signals according to the DC voltage signals, and provide the drive control signals to the first drive circuit and the second drive circuit.

In specific implementations, the circuit board may further provide a DC voltage signal to the drive IC, the drive IC generating a drive control signal based on the DC voltage signal.

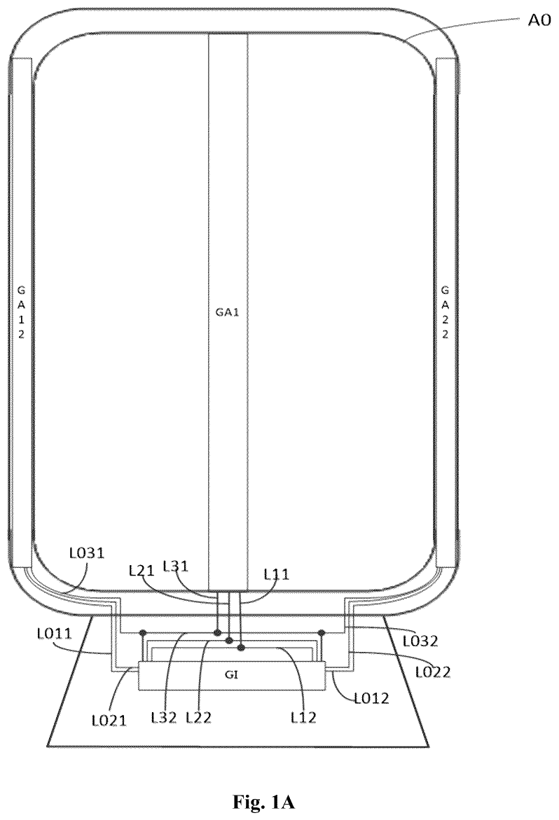

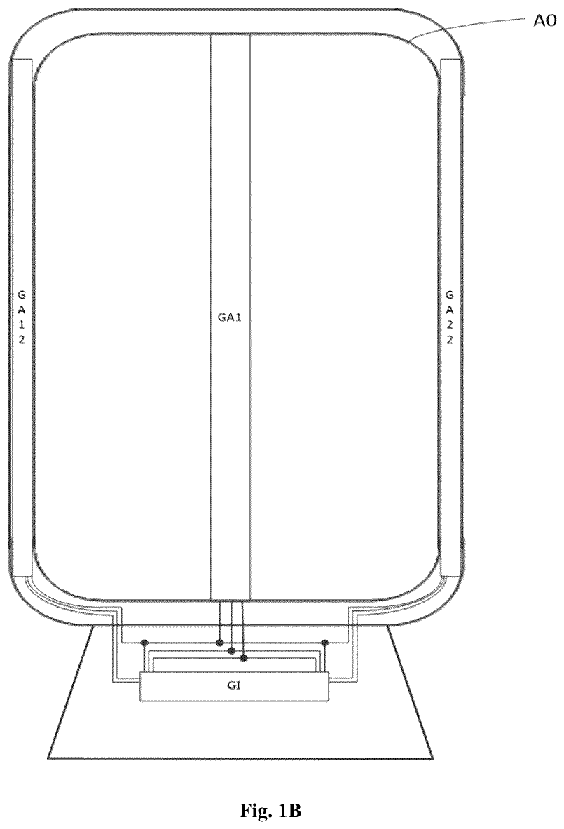

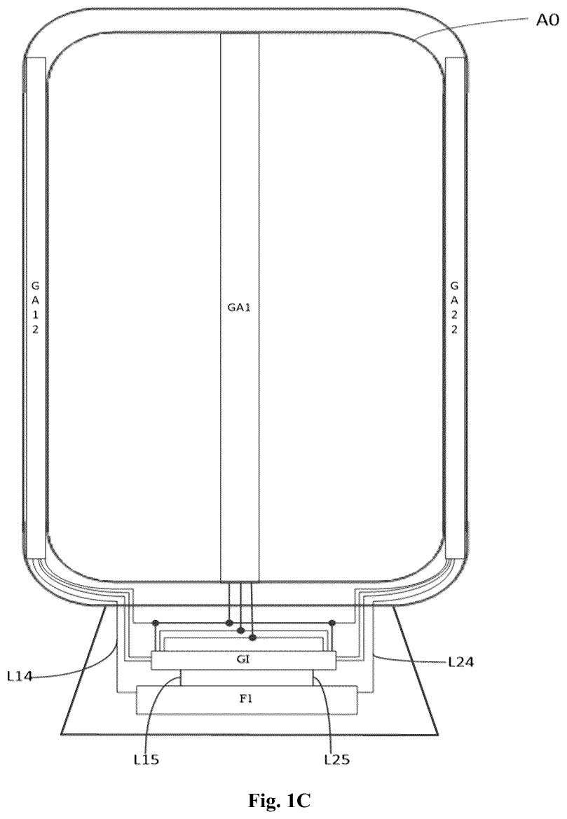

As shown in FIG. 1A, reference numeral P1 denotes a display panel, reference numeral A0 denotes a display area, reference numeral GA1 denotes a first drive module, the first drive module GA1 includes a multi-stage first drive circuit, reference numeral GA12 denotes a first second drive module, the first second drive module GA12 includes a multi-stage second drive circuit, reference numeral GA22 denotes a second second drive module, and the second second drive module GA22 includes a multi-stage second drive circuit.

GA1 is arranged in the middle of the display area A0, GA12 and GA22 are arranged in the peripheral area, GA12 is arranged on the left side of the display area A0, and GA22 is arranged on the right side of the display area A0.

The GA1 is electrically connected to the drive IC GI via a first first GOA signal line L11 extending in a vertical direction and a first second GOA signal line L12 extending in a horizontal direction.

The GA1 is electrically connected to the drive IC GI via a second first GOA signal line L21 extending in a vertical direction and a second second GOA signal line L22 extending in a horizontal direction.

The GA1 is electrically connected to the drive IC GI via a third first GOA signal line L31 extending in a vertical direction and a third second GOA signal line L32 extending in a horizontal direction.

The first first GOA signal line L11 and the first second GOA signal line L12 can be configured to provide a clock signal.

The second first GOA signal line L21 and the second second GOA signal line L22 can be configured to provide a start signal;
the third first GOA signal line L31 and the third second GOA signal line L32 can be configured to provide a gating signal.

The drive IC GI is arranged at the lower side of the display area A0.

L11 is electrically connected to L12, L21 and L22 are electrically connected, and L31 and L32 are electrically connected.

L12 is electrically connected to a port near a left end portion of the drive IC GI, and L12 is electrically connected to a port near a right end portion of the drive IC GI; L22 is electrically connected to a port near a left end portion of the drive IC GI, and L22 is electrically connected to a port near a right end portion of the drive IC GI; L32 is electrically connected to a port near a left end portion of the drive IC GI, and L32 is electrically connected to a port near a right end portion of the drive IC GI.

A first second drive module GA12 is electrically connected to the third second GOA signal line L32; a second second drive module GA22 is electrically connected to the third second GOA signal line L32; and the first second drive module GA12 and the second second drive module GA22 receive the gating signal via the third second GOA signal line L32.

In at least one embodiment of the present disclosure, the display panel may be a locally variable frequency display panel, and GA1 and GA12 and GA22 may share, but are not limited to, a strobe signal.

As shown in FIG. 1A, reference numeral L011 denotes a first first signal line, reference numeral L021 denotes a second first signal line, and reference numeral L031 denotes a third first signal line.

The reference sign L012 is a first second signal line, the reference sign L022 is a second second signal line, and the reference sign L032 is a third second signal line.

L011, L021, L031, L012, L022, and L032 may all be GOA signal lines.

GA12 is electrically connected to L32 via L031, and GA22 is electrically connected to L32 via L032.

The GA12 can receive a clock signal from the drive IC GI via the L011, and the GA12 can receive a start signal from the drive IC GI via the L021.

The GA22 may receive a clock signal from the drive IC GI through L012, and the GA22 may receive a start signal from the drive IC GI through L022.

FIG. 1B is a schematic diagram of signal lines not shown on the basis of FIG. 1A.

In specific implementations, the number of GOA signal lines between the GA1 and the drive IC GI is not limited to three, and may be greater than three.

The number of GOA signal lines between the GA12 and the drive IC GI is not limited to three, and may be greater than three.

The number of GOA signal lines between the GA22 and the drive IC GI is not limited to three, and may be greater than three.

In at least one embodiment of the display panel shown in FIG. 1A, FIG. 1B, the arrangement of GA1 in the display area A0, GA1 is electrically connected to the drive IC GI through L11, L21 and L31 extending in the vertical direction, reducing the space occupied by the GOA signal lines, enabling a narrower lower rounded bezel, and a smaller size of the lower pad area.

In at least one embodiment shown in FIGS. 1A, 1B, the second GOA signal line L2 may be arranged between the bending area and the box-forming testing area.

In at least one embodiment shown in FIGS. 1A and 1B of the present disclosure, a first drive module GA1 is placed in the middle of a display area A0, a first second drive module GA12 is arranged on the left bezel of the display panel, a second second drive module GA22 is arranged on the right bezel of the display panel, and the first drive module GA1 placed in the middle of the display area A0 passes through a first GOA signal line extending in a vertical direction and a second GOA signal line extending in a horizontal direction and arranged between a bending area and a box-forming testing area; drive control signals from the drive IC GI are received from a port near the left end portion of the drive IC GI and a port near the right end portion of the drive IC GI, which are electrically connected to the drive IC GI, without changing the drive IC GI to assist in changing the design. At least one embodiment of the display panel shown in FIGS. 1A and 1B of the present disclosure can reduce the space occupied by the GOA signal lines at the lower corner bezel, make full use of the space of the lower pad area, and reduce the size of the lower pad area, to improve the screen occupation ratio. In at least one embodiment of the display panel shown in FIG. 1 of the present disclosure, the GOA signal line uses a film layer having no interference with other cells of the current area as far as possible, for example, the second GOA signal line may be formed on the second source/drain metal layer, but this is not a limitation.

In at least one embodiment of the present disclosure 1A and 1B of the present disclosure, the second GOA signal line may further be electrically connected to a port arranged at a left end portion of the drive IC GI and a port arranged at a right end portion of the drive IC GI, but is not limited thereto.

As shown in FIG. 1C, on the basis of at least one embodiment of the display panel shown in FIG. 1B, the display panel according to at least one embodiment of the present disclosure may further include a circuit board F1.

The circuit board F1 is arranged on a side of the drive IC GI away from the display area A0.

The circuit board F1 is electrically connected to the first drive module GA1, the first second drive module GA12 and the second second drive module GA22 for providing a DC voltage signal for the first drive module GA1, the first second drive module GA12 and the second second drive module GA22; for example, the DC voltage signal arranged by the circuit board F1 to each drive module may include, for example, a high-voltage signal VGH, a first low-voltage signal LVGL and a second low-voltage signal VGL, but this is not a limitation.

The circuit board F1 is further electrically connected to the drive IC GI for providing a DC voltage signal to the drive IC GI; for example, the DC voltage signal arranged by the circuit board F1 to the drive IC GI may include, for example: at least one of a high voltage signal (VGH), a first low voltage signal (LVGL), a second low voltage signal (VGL), a high level signal (VDD) and a low level signal (VSS), but not limited thereto.

The drive IC GI is configured to generate a drive control signal according to the DC voltage signal, and provide the drive control signal to the first drive circuit and the second drive circuit.

In specific implementations, the drive IC GI can further be configured to provide data lines arranged in a display area with data voltage.

The circuit board F1 is configured to provide a DC voltage signal to a drive IC GI so that the drive IC GI generates a drive control signal according to the DC voltage signal.

The circuit board F1 is configured to provide a DC voltage signal to each drive module, so that each drive module generates a drive signal according to the DC voltage signal.

In FIG. 1C, reference numeral L14 is a first DC signal transmission line, reference numeral L24 is a second DC signal transmission line, reference numeral L15 is a third DC signal transmission line, and reference numeral L25 is a fourth DC signal transmission line.

The circuit board F1 provides a DC voltage signal to the GA12 via L14, to the GA22 via L24, and to the GI via L15 and L25.

In FIG. 1C, a voltage signal line for transmitting a DC voltage signal between the circuit board F1 and the first drive module GA1 is not shown.

Optionally, a fan-out area, a bending area, a box-forming testing area, and an area where the drive IC is arranged are sequentially arranged at the first side of the display area in a direction away from the display area.

The second GOA signal lines are arranged between the bending area and the box-forming testing area.

In specific implementations, a fan-out area, a bending area, a box-forming testing area and an area where the drive IC is arranged may be arranged in sequence on a first side of the display area in a direction away from the display area, and the second GOA signal line may be arranged between the bending area and the box-forming testing area. Optionally, the first side may be but is not limited to, the lower side.

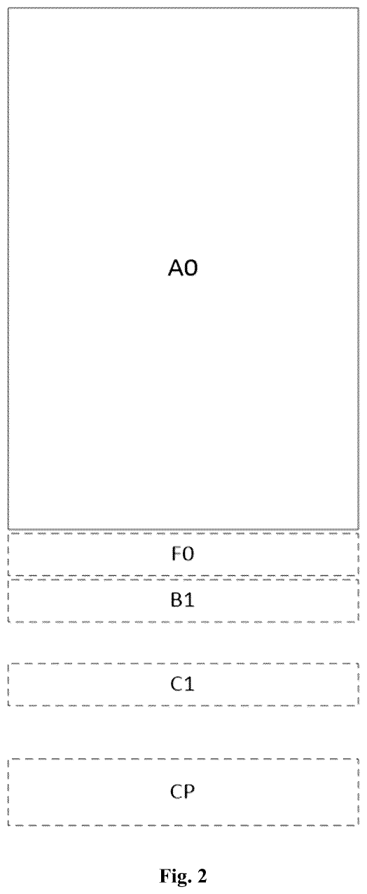

As shown in FIG. 2, reference numeral A0 denotes a display area, reference numeral F0 denotes a fan-out area, reference numeral Bl denotes a bending area, reference numeral C1 denotes a box-forming testing area, and reference numeral CP denotes an area where the drive IC is arranged.

On the lower side of the display area A0, in a direction away from the display area A0, a fan-out area F0, a bending area B1, a box-forming testing area C1, and an area CP where the drive IC is arranged in this order.

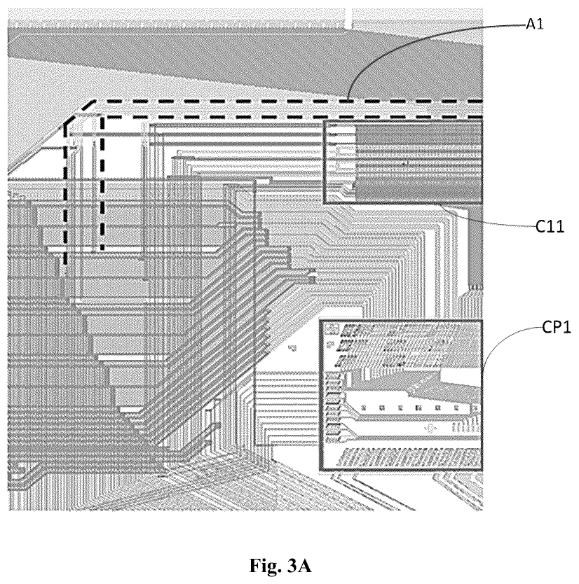

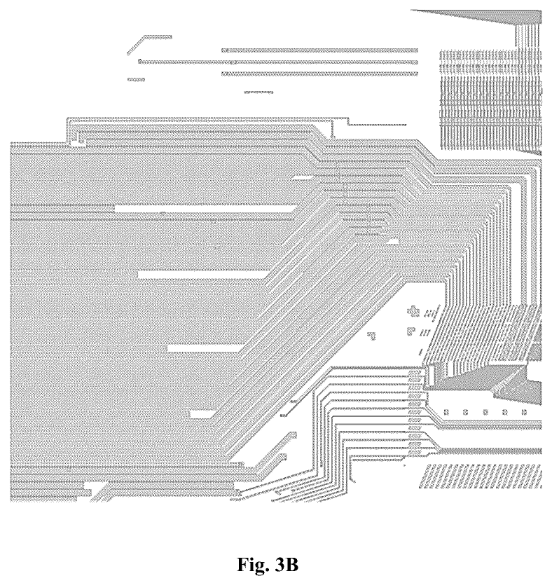

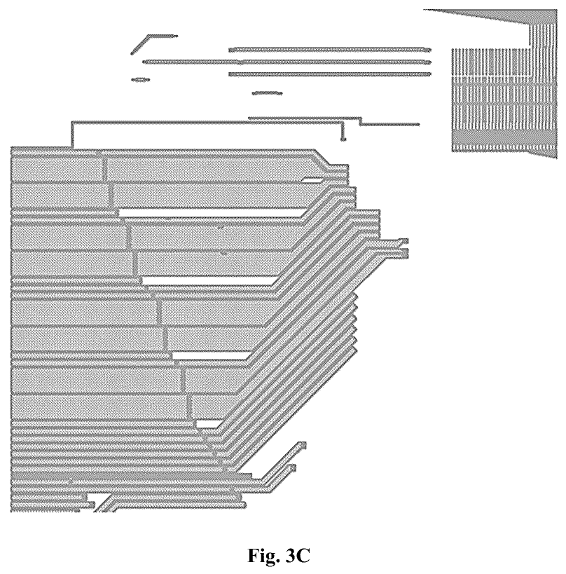

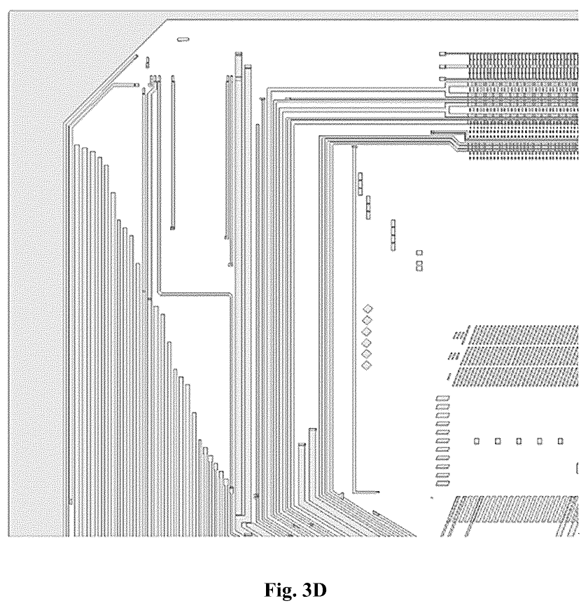

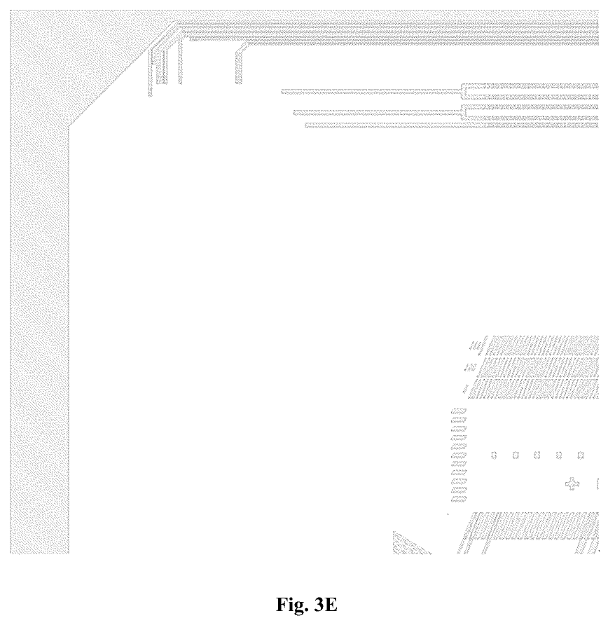

FIG. 3A is a layout diagram of a partial area of a lower pad area of a display panel according to at least one embodiment of the present disclosure.

In FIG. 3A, an area where a part of the signal lines of the second GOA signal line is arranged is designated by reference numeral A1, an area in the box-forming testing area is designated by reference numeral C11, and an area in the area where the drive IC is arranged is denoted by reference numeral CP1.

FIG. 3B is a layout diagram of the first gate metal layer in FIG. 3A, FIG. 3C is a layout diagram of the second gate metal layer in FIG. 3A, FIG. 3D is a layout diagram of the first source-drain metal layer in FIG. 3A, and FIG. 3E is a layout diagram of the second source-drain metal layer in FIG. 3A.

In FIG. 3E, reference numeral A1 denotes an area where part of the signal lines of a second GOA signal line are arranged, part of the signal lines of the second GOA signal line are arranged in A1, and the second GOA signal line is formed in a second source and drain metal layer.

As shown in FIGS. 3A, 3D, and 3E, a second GOA signal line formed on a second source and drain metal layer is electrically connected to a transition line extending in a vertical direction at a portion formed on the first source and drain metal layer.

As shown in FIGS. 3A-3E, an adapter line formed on a first source and drain metal layer is electrically connected to an adapter line formed on a portion of a second gate metal layer extending in a horizontal direction.

As shown in FIGS. 3A-3E, the transition line formed in the second gate metal layer is electrically connected to the transition line formed in the first gate metal layer and the drive IC.

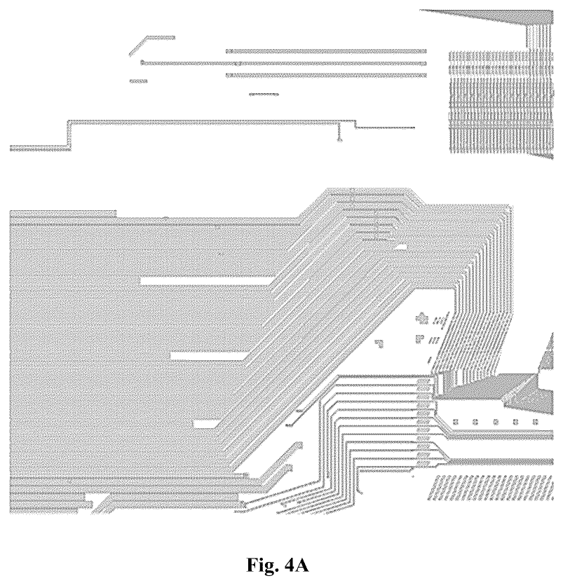

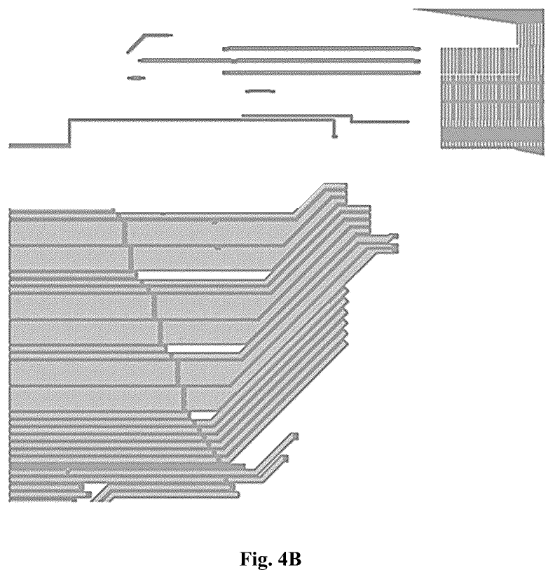

FIG. 4A is a layout diagram of a first gate metal layer in at least one embodiment of the present disclosure, and FIG. 4B is a layout diagram of a second gate metal layer in at least one embodiment of the present disclosure.

Compared to FIG. 3B, in at least one embodiment shown in FIG. 4A, a plurality of lateral signal lines are reduced, which may be GOA signal lines arranged between the drive modules of the peripheral area and the drive IC GI.

Compared to FIG. 3C, in at least one embodiment shown in FIG. 4B, a plurality of rows of lateral signal lines are reduced, which may be GOA signal lines arranged between the drive modules of the peripheral area and the drive IC GI.

In at least one embodiment of the present disclosure, the number of GOA signal lines arranged between the drive module arranged in the peripheral area and the drive IC GI can be reduced by providing GA1 in the display area and receiving the GOA control signal, by GA1, from the drive IC GI through the GOA signal line in the vertical direction.

In at least one embodiment of the present disclosure, at least some of the first GOA signal lines are electrically connected directly to the drive IC for receiving drive control signals from the drive IC.

In specific implementations, at least some of the first GOA signal lines may be directly electrically coupled to the drive IC to receive drive control signals from the drive IC.

In at least one embodiment of the present disclosure, the GOA signal line further includes a second GOA signal line extending in a second direction; the first direction intersects the second direction.

Part of the first GOA signal lines are electrically connected to the second GOA signal lines.

In specific implementations, the GOA signal line may further include a second GOA signal line extending in a second direction, such as, but not limited to, a horizontal direction.

In at least one embodiment of the present disclosure, the first GOA signal line may be electrically connected to a port located in the middle of the drive IC, to reduce the length of a connecting line of the first GOA signal line, reduce the length of a winding of the first GOA signal line, and reduce the load of the first GOA signal line.

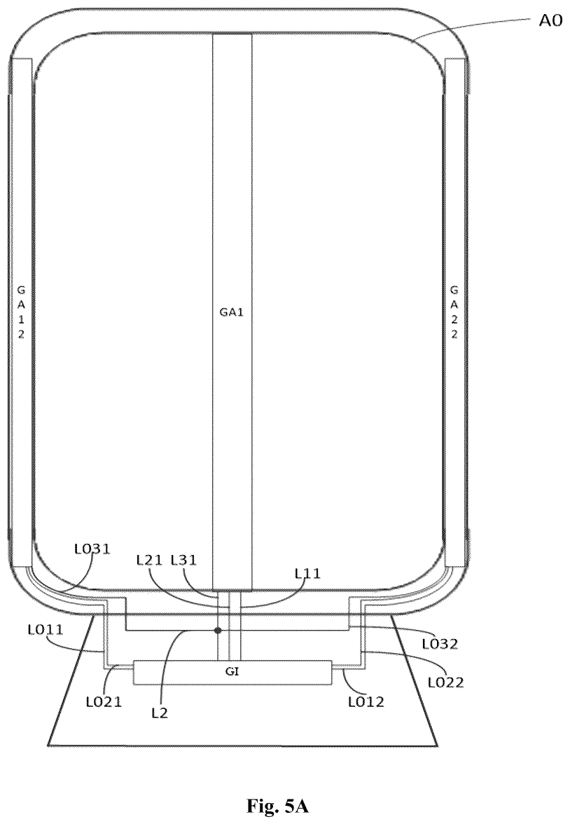

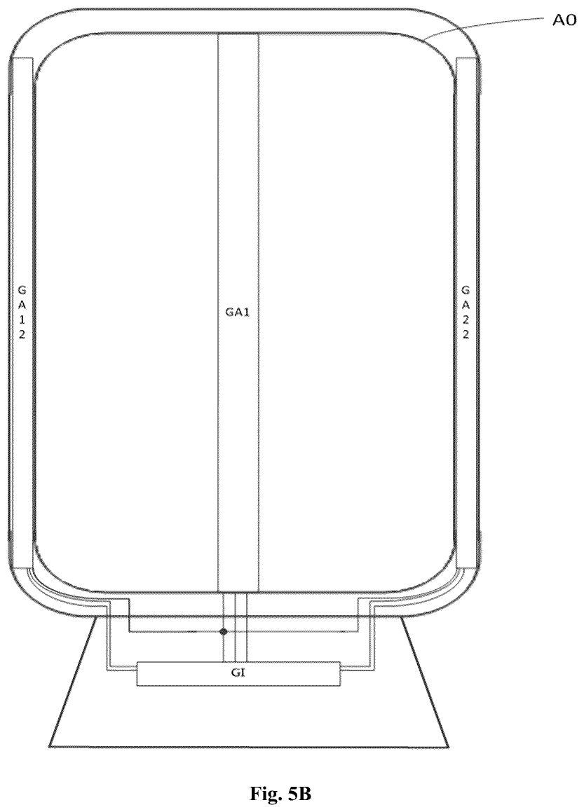

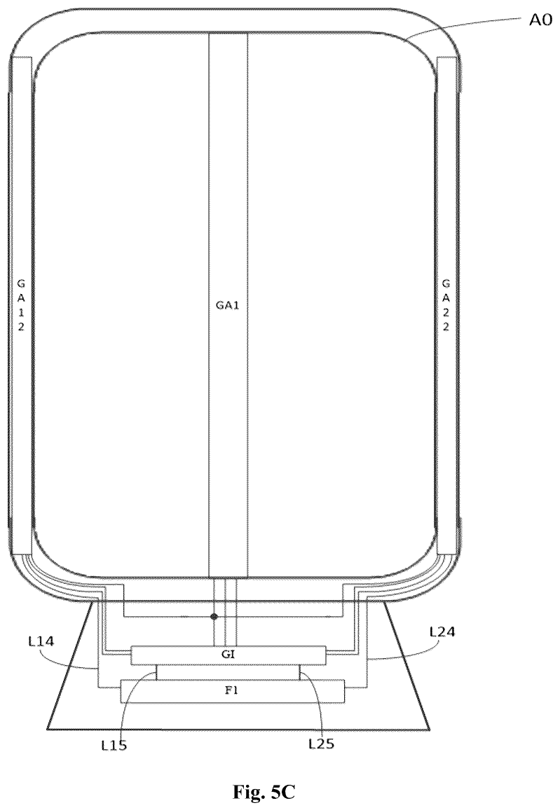

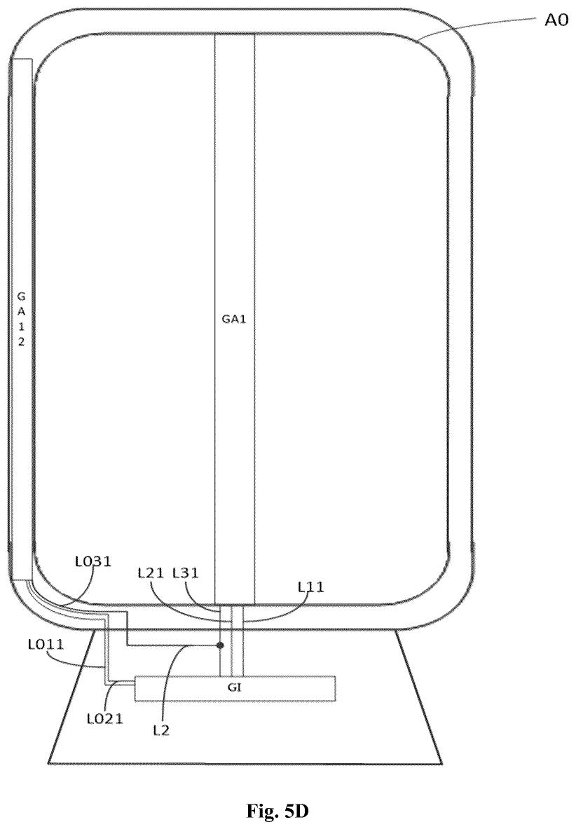

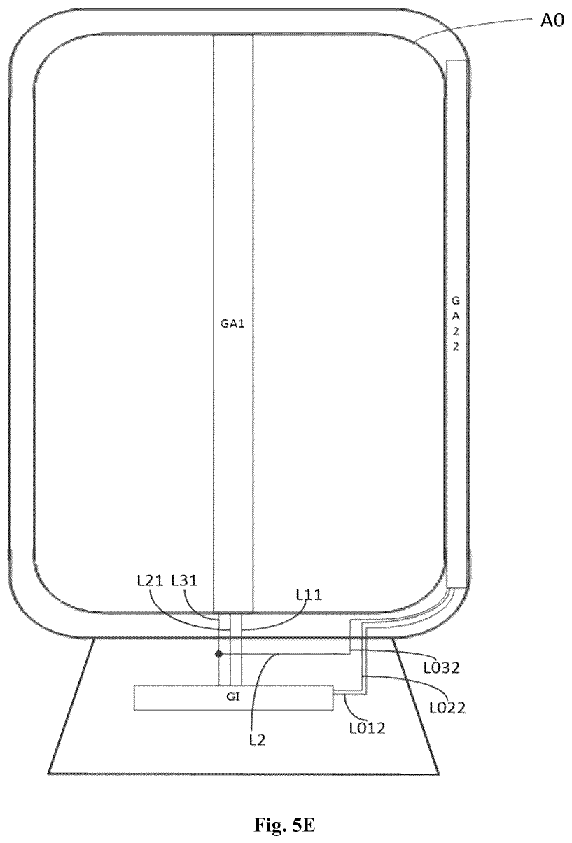

As shown in FIG. 5A, reference numeral Pl denotes a display panel, reference numeral A0 denotes a display area, reference numeral GA1 denotes a first drive module, the first drive module GA1 includes a multi-stage first drive circuit, reference numeral GA12 denotes a first second drive module, the first second drive module includes a multi-stage second drive circuit, reference numeral GA22 denotes a second second drive module, and the second second drive module GA22 includes a multi-stage second drive circuit.

GA1 is arranged in the middle of the display area A0, GA12 and GA22 are arranged in the peripheral area, GA12 is arranged on the left side of the display area A0, and GA22 is arranged on the right side of the display area A0.

The GA1 is electrically connected to a port arranged in the middle of the drive IC GI via a first first GOA signal line L11 extending in a vertical direction, and the GA1 receives a clock signal from the drive IC GI via the L11.

The GA1 is electrically connected to a port arranged in the middle of the drive IC GI via a second first GOA signal line L21 extending in a vertical direction; GA1 receives a start signal from the drive IC GI via L21.

The GA1 is electrically connected to a port arranged in the middle part of the drive IC GI via a third first GOA signal line L31 extending in a vertical direction, and the GA1 receives a gating signal from the drive IC GI via the L31.

L31 is electrically connected to a second GOA signal line L2 extending along the horizontal direction, and L2 is electrically connected to GA12 and GA22 for providing gating signals for GA12 and GA22.

GA12, GA22, and GA1 share a strobe signal.

As shown in FIG. 5A, reference numeral L011 denotes a first first signal line, reference numeral L021 denotes a second first signal line, and reference numeral L031 denotes a third first signal line.

The reference sign L012 is a first second signal line, the reference sign L022 is a second second signal line, and the reference sign L032 is a third second signal line.

L011, L021, L031, L012, L022, and L032 may all be GOA signal lines.

GA12 is electrically connected to L2 via L031, and GA22 is electrically connected to L2 via L032.

The GA12 can receive a clock signal from the drive IC GI via the L011, and the GA12 can receive a start signal from the drive IC GI via the L021.

The GA22 may receive a clock signal from the drive IC GI through L012, and the GA22 may receive a start signal from the drive IC GI through L022.

In at least one embodiment shown in FIG. 5A, a drive IC GI is arranged on the lower side of the display area A0.

The first drive module GA1 arranged in the display area is directly electrically connected to the drive IC GI through L11, L21, and L31 extending in the vertical direction, so that the length of the GOA signal line winding can be reduced, and the load of the GOA signal line can be reduced; and at least one embodiment of the display panel shown in FIG. 5A can reduce the space occupied by the GOA signal line at the lower corner bezel, reduce the size of the lower pad area, and make full use of the space in the middle section of the drive IC GI, and further shorten the width of the drive IC GI and the size of the lower pad area.

In at least one embodiment of the display panel shown in FIG. 5A, the GOA signal lines use as much as possible a film layer that does not interfere with other cells in the current area and other cell designs may further be modified in conjunction with the GOA signal lines.

In at least one embodiment shown in FIG. 5A, the second GOA signal line L2 may be arranged between, but is not limited to, the bending area and the box-forming testing area.

Compared to the at least one embodiment shown in FIG. 1A, in the at least one embodiment shown in FIG. 5A, only one second GOA signal line extending in the horizontal direction is arranged, the number of second GOA signal lines arranged in the lower pad area is reduced, and the size of the lower pad area can be reduced.

FIG. 5B is a schematic diagram of signal lines not shown based on FIG. 5A.

In specific implementations, the number of GOA signal lines between the GA1 and the drive IC GI is not limited to three and may be greater than three.

The number of GOA signal lines between the GA12 and the drive IC GI is not limited to three and may be greater than three.

The number of GOA signal lines between the GA22 and the drive IC GI is not limited to three and may be greater than three.

As shown in FIG. 5C, the display panel according to at least one embodiment of the present disclosure may further include a circuit board F1.

The circuit board F1 is arranged on a side of the drive IC GI away from the display area A0.

The circuit board F1 is electrically connected to the first drive module GA1, the first second drive module GA12 and the second second drive module GA22 for providing a DC voltage signal for the first drive module GA1, the first second drive module GA12 and the second second drive module GA22.

The circuit board F1 is further electrically connected to the drive IC GI for providing a DC voltage signal to the drive IC GI.

The drive IC GI is configured to generate a drive control signal according to the DC voltage signal and provide the drive control signal to a first drive module GA1, a first second drive module GA12, and a second second drive module GA22.

In FIG. 5C, reference numeral L14 is the first DC signal transmission line, reference numeral L24 is a second DC signal transmission line, reference numeral L15 is a third DC signal transmission line, and reference numeral L25 is a fourth DC signal transmission line.

The circuit board F1 provides a DC voltage signal to the GA12 via L14, to the GA22 via L24, and to the GI via L15 and L25.

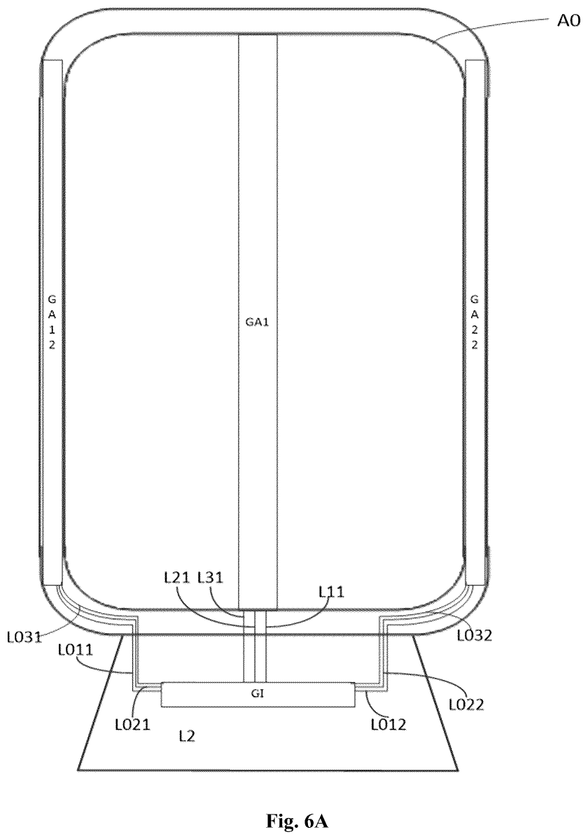

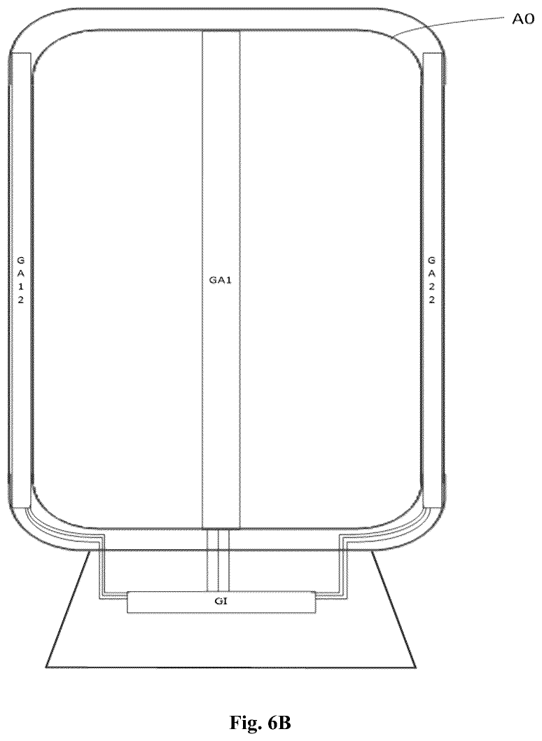

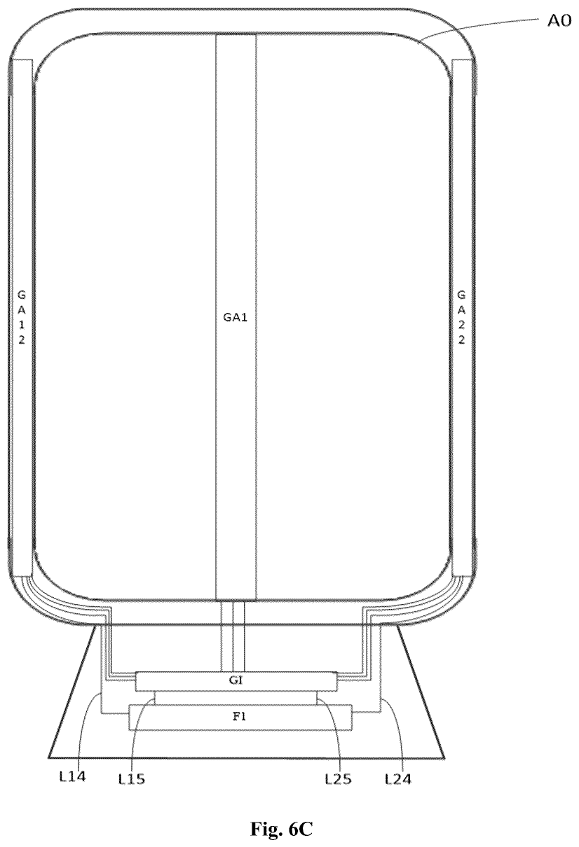

In FIG. 5C, a voltage signal line for transmitting a DC voltage signal between the circuit board F1 and the first drive module GA1 is not shown. As shown in FIG. 6A, reference numeral P1 denotes a display panel, reference numeral A0 denotes a display area, reference numeral GA1 denotes a first drive module, the first drive module GA1 includes a multi-stage first drive circuit, reference numeral GA12 denotes a first second drive module, the first second drive module includes a multi-stage second drive circuit, reference numeral GA22 denotes a second second drive module, and the second second drive module GA22 includes a multi-stage second drive circuit.

GA1 is arranged in the middle of the display area A0, GA12 and GA22 are arranged in the peripheral area, GA12 is arranged on the left side of the display area A0, and GA22 is arranged on the right side of the display area A0.

The GA1 is electrically connected to a port arranged in the middle of the drive IC GI via a first first GOA signal line L11 extending in a vertical direction, and the GA1 receives a clock signal from the drive IC GI via the L11.

The GA1 is electrically connected to a port arranged in the middle of the drive IC GI via a second first GOA signal line L21 extending in a vertical direction; GA1 receives a start signal from the drive IC GI via L21.

GA1 is electrically connected to a port arranged in the middle of the drive IC GI through a third first GOA signal line L31 extending in the vertical direction, and GA1 receives a strobe signal from the drive IC GI through L31.

Optionally, the second drive module may be arranged on the left and/or right side of the display area A0.

As shown in FIG. 5D, reference numeral P1 denotes a display panel, reference numeral A0 denotes a display area, reference numeral GA1 denotes a first drive module, the first drive module GA1 includes a multi-stage first drive circuit, reference numeral GA12 denotes a first second drive module, and the first second drive module includes a multi-stage second drive circuit.

GA1 is arranged in the middle of the display area A0, GA12 is arranged in the peripheral area, and GA12 is arranged on the left side of the display area A0.

The GA1 is electrically connected to a port arranged in the middle of the drive IC GI via a first first GOA signal line L11 extending in a vertical direction, and the GA1 receives a clock signal from the drive IC GI via the L11.

The GA1 is electrically connected to a port arranged in the middle of the drive IC GI via a second first GOA signal line L21 extending in a vertical direction; GA1 receives a start signal from the drive IC GI via L21.

The GA1 is electrically connected to a port arranged in the middle part of the drive IC GI via a third first GOA signal line L31 extending in a vertical direction, and the GA1 receives a gating signal from the drive IC GI via the L31.

L31 is electrically connected to a second GOA signal line L2 extending in a horizontal direction, and L2 is electrically connected to the GA12 to provide a gating signal for the GA12 and the GA22.

GA12 and GA1 share a strobe signal.

As shown in FIG. 5D, reference numeral L011 denotes a first first signal line, reference numeral L021 denotes a second first signal line, and reference numeral L031 denotes a third first signal line.

L011, L021, and L031 may all be GOA signal lines.

GA12 is electrically connected to L2 through L031.

The GA12 may receive a clock signal from the drive IC GI through L011, and the GA12 may receive a start signal from the drive IC GI through L021.

In at least one embodiment shown in FIG. 5D, a drive IC GI is arranged on the lower side of the display area A0.

The first drive module GA1 arranged in the display area is directly electrically connected to the drive IC GI via L11, L21, and L31 extending in the vertical direction, so that the length of the GOA signal line winding can be reduced, and the load of the GOA signal line can be reduced; and at least one embodiment of the display panel shown in FIG. 5D can reduce the space occupied by the GOA signal line at the lower corner bezel, reduce the size of the lower pad area, and make full use of the space in the middle section of the drive IC GI to further shorten the width of the drive IC GI and the size of the lower pad area.

As shown in FIG. 5E, reference numeral P1 denotes a display panel, reference numeral A0 denotes a display area, reference numeral GA1 denotes a first drive module, the first drive module GA1 includes a multi-stage first drive circuit, reference numeral GA22 denotes a second second drive module, and the second second drive module GA22 includes a multi-stage second drive circuit.

GA1 is arranged in the middle of the display area A0, GA22 is arranged in the peripheral area, and GA22 is arranged on the right side of the display area A0.

The GA1 is electrically connected to a port arranged in the middle of the drive IC GI via a first first GOA signal line L11 extending in a vertical direction, and the GA1 receives a clock signal from the drive IC GI via the L11.

The GA1 is electrically connected to a port arranged in the middle of the drive IC GI via a second first GOA signal line L21 extending in a vertical direction; GA1 receives a start signal from the drive IC GI via L21.

The GA1 is electrically connected to a port arranged in the middle part of the drive IC GI via a third first GOA signal line L31 extending in a vertical direction, and the GA1 receives a gating signal from the drive IC GI via the L31.

L31 is electrically connected to a second GOA signal line L2 extending in a horizontal direction, and L2 is electrically connected to the GA22 for providing a gating signal for the GA22.

GA22 and GA1 share a strobe signal.

As shown in FIG. 5E, reference numeral L012 denotes a first second signal line, reference numeral L022 denotes a second second signal line, and reference numeral L032 denotes a third second signal line.

L012, L022, and L032 may all be GOA signal lines.

GA22 is electrically connected to L2 through L032.

The GA22 may receive a clock signal from the drive IC GI through L012, and the GA22 may receive a start signal from the drive IC GI through L022.

In at least one embodiment shown in FIG. 5E, a drive IC GI is arranged on the lower side of the display area A0.

The first drive module GA1 arranged in the display area is directly electrically connected to the drive IC GI via L11, L21 and L31 extending in the vertical direction, so that the length of the GOA signal line winding can be reduced, and the load of the GOA signal line can be reduced; and at least one embodiment of the display panel shown in FIG. 5E can reduce the space occupied by the GOA signal line at the lower corner bezel, reduce the size of the lower pad area, and make full use of the space in the middle section of the drive IC GI to further shorten the width of the drive IC GI and the size of the lower pad area.

As shown in FIG. 6A, reference numeral L011 denotes a first first signal line, reference numeral L021 denotes a second first signal line, and reference numeral L031 denotes a third first signal line.

The reference sign L012 is a first second signal line, the reference sign L022 is a second second signal line, and the reference sign L032 is a third second signal line.

L011, L021, L031, L012, L022, and L032 may all be GOA signal lines.

The GA12 can receive a clock signal from the drive IC GI via the L011, and the GA12 can receive a start signal from the drive IC GI via the L021; the GA12 can receive a gating signal from the drive IC GI via the L031.

The GA22 can receive a clock signal from the drive IC GI via the L012, and the GA22 can receive a start signal from the drive IC GI via the L022; the GA22 may receive a strobe signal from the drive IC GI through L032.

In at least one embodiment shown in FIG. 6A, GA1, and GA12 are not electrically connected to the same GOA signal line, GA1 and GA22 are not electrically connected to the same GOA signal line, GA1 receives a strobe signal through L31, GA12 receives a strobe signal through L031, and GA22 receives a strobe signal through L032.

In at least one embodiment shown in FIG. 6A, a drive IC GI is arranged on the lower side of the display area A0.

The first drive module GA1 arranged in the display area is directly electrically connected to the drive IC GI through L11, L21, and L31 extending in the vertical direction, so that the length of the GOA signal line winding can be reduced, and the load of the GOA signal line can be reduced; and at least one embodiment of the display panel shown in FIG. 6A can reduce the space occupied by the GOA signal line at the lower corner bezel, reduce the size of the lower pad area, and make full use of the space in the middle section of the drive IC GI, and further shorten the width of the drive IC GI and the size of the lower pad area.

In at least one embodiment of the display panel shown in FIG. 6A, the GOA signal lines use as much as possible a film layer that does not interfere with other cells in the current area, and other cell designs may further be modified in conjunction with the GOA signal lines.

In at least one embodiment shown in FIG. 6A, the second GOA signal line L2 may be arranged between, but is not limited to, the bending area and the box-forming testing area.

In comparison to the at least one embodiment shown in FIG. 1A, in the at least one embodiment shown in FIG. 6A, the second GOA signal lines extending in the horizontal direction are not arranged, the number of second GOA signal lines arranged in the lower pad area employed is reduced, and the size of the lower pad area can be reduced.

FIG. 6B is a schematic diagram of signal lines not shown based on FIG. 6A.

In specific implementations, the number of GOA signal lines between the GA1 and the drive IC GI is not limited to three and may be greater than three.

The number of GOA signal lines between the GA12 and the drive IC GI is not limited to three and may be greater than three.

The number of GOA signal lines between the GA22 and the drive IC GI is not limited to three and may be greater than three.

As shown in FIG. 6C, the display panel according to at least one embodiment of the present disclosure may further include a circuit board F1.

The circuit board F1 is arranged on a side of the drive IC GI away from the display area A0.

The circuit board F1 is electrically connected to the first drive module GA1, the first second drive module GA12 and the second second drive module GA22 for providing a DC voltage signal for the first drive module GA1, the first second drive module GA12 and the second second drive module GA22.

The circuit board F1 is further electrically connected to the drive IC GI for providing a DC voltage signal to the drive IC GI.

The drive IC GI is configured to generate a drive control signal according to the DC voltage signal and provide the drive control signal to a first drive module GA1, a first second drive module GA12, and a second second drive module GA22.

In FIG. 6C, reference numeral L14 is a first DC signal transmission line, reference numeral L24 is a second DC signal transmission line, reference numeral L15 is a third DC signal transmission line and reference numeral L25 is a fourth DC signal transmission line.

The circuit board F1 provides a DC voltage signal to the GA12 via L14, to the GA22 via L24, and to the GI via L15 and L25.

In FIG. 6C, a voltage signal line for transmitting a DC voltage signal between the circuit board F1 and the first drive module GA1 is not shown.

In at least one embodiment of the present disclosure, the GOA signal line further includes a second GOA signal line, the second GOA signal line extending in a second direction; the first direction intersects the second direction.

The first GOA signal lines are directly connected to the second GOA signal lines.

A fan-out area, a bending area, a box-forming testing area, and an area where the drive IC is arranged are sequentially arranged at the first side of the display area in a direction away from the display area.

The second GOA signal lines are arranged in the fan-out area.

The second GOA signal lines are electrically connected to the drive IC.

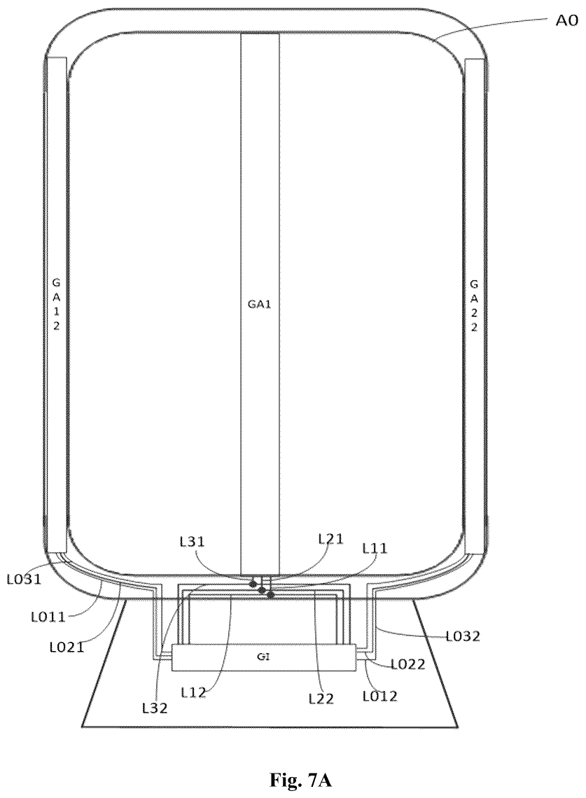

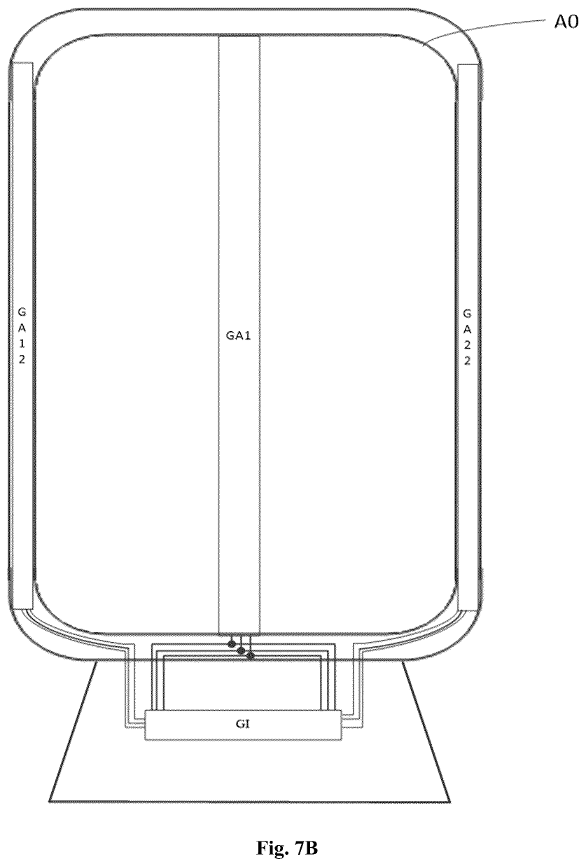

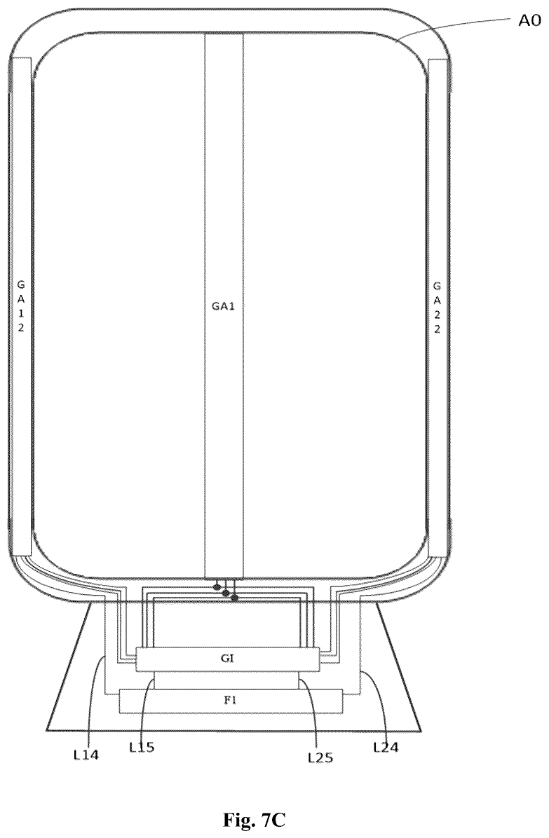

As shown in FIG. 7A, reference numeral P1 denotes a display panel, reference numeral A0 denotes a display area, reference numeral GA1 denotes a first drive module, the first drive module GA1 includes a multi-stage first drive circuit, reference numeral GA12 denotes a first second drive module, the first second drive module GA12 includes a multi-stage second drive circuit, reference numeral GA22 denotes a second second drive module, and the second second drive module GA22 includes a multi-stage second drive circuit.

GA1 is arranged in the middle of the display area A0, GA12 and GA22 are arranged in the peripheral area, GA12 is arranged on the left side of the display area A0, and GA22 is arranged on the right side of the display area A0.

The GA1 is electrically connected to the drive IC GI via a first first GOA signal line L11 extending in a vertical direction and a first second GOA signal line L12 extending in a horizontal direction.

The GA1 is electrically connected to the drive IC GI via a second first GOA signal line L21 extending in a vertical direction and a second second GOA signal line L22 extending in a horizontal direction.

The GA1 is electrically connected to the drive IC GI via a third first GOA signal line L11 extending in a vertical direction and a third second GOA signal line L12 extending in a horizontal direction.

GA1 is directly electrically connected to L11, and L11 is directly electrically connected to L12; GA1 is directly electrically connected to L21, and L21 is directly electrically connected to L22; GA1 is directly electrically connected to L31, and L31 is directly electrically connected to L32.

GA1 receives a clock signal from the drive IC GI via L11 and L12, GA1 receives a start signal from the drive IC GI via L21 and L22, and GA1 receives a gating signal from the drive IC GI via L31 and L32.

The drive IC GI is arranged at the lower side of the display area A0.

L11, L21, and L31 are all arranged in the fan-out area.

L12, L22, and L32 are all arranged in the fan-out area, to avoid arranging the GOA signal line in the lower pad area, saving space for the lower bezel, facilitating the realization of a narrow lower rounded bezel, and a small size of a lower pad area.

As shown in FIG. 7A, reference numeral L011 denotes a first first signal line, reference numeral L021 denotes a second first signal line, and reference numeral L031 denotes a third first signal line.

The reference sign L012 is a first second signal line, the reference sign L022 is a second second signal line, and the reference sign L032 is a third second signal line.

L011, L021, L031, L012, L022, and L032 may all be GOA signal lines.

GA12 is electrically connected to L2 via L031, and GA22 is electrically connected to L2 via L032.

The GA12 can receive a clock signal from the drive IC GI via the L011, and the GA12 can receive a start signal from the drive IC GI via the L021.

The GA22 may receive a clock signal from the drive IC GI through L012, and the GA22 may receive a start signal from the drive IC GI through L022.

In at least one embodiment of the display panel shown in FIG. 7A, the GOA signal lines use as much as possible a film layer that does not interfere with other cells in the current area and other cell designs may further be modified in conjunction with the GOA signal lines.

In at least one embodiment of the display panel shown in FIG. 7A,

Each second GOA signal line is electrically connected to a port near the left end portion of the drive IC GI, and each second GOA signal line is electrically connected to a port near the right end portion of the drive IC GI.

In at least one embodiment of the display panel shown in FIG. 7A, a GOA signal line is arranged above the bending area. The GOA signal line may be made using a film layer that does not interfere with the fan-out area, the high voltage line, and the low voltage line, such as a BSM layer, or a third gate metal layer. At least one embodiment of the display panel shown in FIG. 7A of the present disclosure may implement the design of the GOA signal lines without modifying the design of the lower pad area, reducing the lower corner bezel width of the display panel, and eliminating the need for the drive IC GI to assist in varying the design.

In specific implementations, the film associated with the fan-out area may include a first gate metal layer and a second gate metal layer, the film associated with the high voltage line and the low voltage line may include a first source-drain metal layer and a second source-drain metal layer, and the GOA signal line may be fabricated using film layers other than the first gate metal layer, the second gate metal layer, the first source-drain metal layer, and the second source-drain metal layer.

FIG. 7B is a schematic diagram of signal lines not shown based on FIG. 7A.

In specific implementations, the number of GOA signal lines between the GA1 and the drive IC GI is not limited to three and may be greater than three.

The number of GOA signal lines between the GA12 and the drive IC GI is not limited to three and may be greater than three.

The number of GOA signal lines between the GA22 and the drive IC GI is not limited to three and may be greater than three.

As shown in FIG. 7C, the display panel according to at least one embodiment of the present disclosure may further include a circuit board F1.

The circuit board F1 is arranged on a side of the drive IC GI away from the display area A0.

The circuit board F1 is electrically connected to the first drive module GA1, the first second drive module GA12 and the second second drive module GA22 for providing a DC voltage signal for the first drive module GA1, the first second drive module GA12 and the second second drive module GA22.

The circuit board F1 is further electrically connected to the drive IC GI for providing a DC voltage signal to the drive IC GI.

The drive IC GI is configured to generate a drive control signal according to the DC voltage signal and provide the drive control signal to a first drive module GA1, a first second drive module GA12, and a second second drive module GA22.

In FIG. 7C, reference numeral L14 is a first DC signal transmission line, reference numeral L24 is a second DC signal transmission line, reference numeral L15 is a third DC signal transmission line and reference numeral L25 is a fourth DC signal transmission line.

The circuit board F1 provides a DC voltage signal to the GA12 via L14, to the GA22 via L24, and to the GI via L15 and L25.

In FIG. 7C, a voltage signal line for transmitting a DC voltage signal between the circuit board F1 and the first drive module GA1 is not shown.

Both the drive IC GI and the circuit board F1 are arranged in the lower pad area.

Optionally, the plurality of second drive circuits are arranged on the second side and the third side of the display area.

A first end portion of the second GOA signal line is electrically connected to a first port of the drive IC.

A second end portion of the second GOA signal line is electrically connected to a second port of the drive IC.

In specific implementations, a first end portion of the second GOA signal line may be a left end portion of the second GOA signal line, and a second end portion of the second GOA signal line may be a right end portion of the second GOA signal line.

A left end portion of the second GOA signal line can be electrically connected to a first port of the drive IC.

A right end portion of the second GOA signal line can be electrically connected to a second port of the drive IC.

The first port of the drive IC may be a port close to the left end portion of the drive IC, or the first port of the drive IC may be a port arranged at the left end portion of the drive IC.

The second port of the drive IC may be a port near the right end portion of the drive IC or the second port of the drive IC may be a port arranged at the right end portion of the drive IC.

In at least one embodiment of the present disclosure, all the drive circuits included in the drive module are arranged in the display area.

The first GOA signal lines are directly electrically connected to the drive IC, for receiving the drive control signals from the drive IC.

In specific implementations, all the drive circuits included in the drive module can be arranged in the display area, and arranged below the anode layer, to sufficiently reduce the left and right bezels of the display panel, facilitating the realization of the left bezel.

The display panel according to at least one embodiment of the present disclosure further includes a voltage signal line.

The voltage signal lines are electrically connected to the drive circuits, for providing DC voltage signals to the drive circuits.

In specific implementations, the display panel may include a voltage signal line that provides a DC voltage signal to a drive circuit located in the display area.

In at least one embodiment of the present disclosure, the voltage signal line is electrically connected to the drive IC for providing a DC voltage signal to the drive IC.

The drive IC is configured to generate the drive control signals according to the DC voltage signals and provide the drive control signals to the drive circuits.

In specific implementations, the voltage signal line may further provide a DC voltage signal to the drive IC.

The display panel of at least one embodiment of the present disclosure further includes a circuit board arranged on the drive IC away from the display area.

The circuit board is electrically connected to the voltage signal lines, for providing the DC voltage signals to the voltage signal lines.

In specific implementations, the display panel may further include a circuit board arranged below the drive IC, the circuit board providing the DC voltage signal to the voltage signal line.

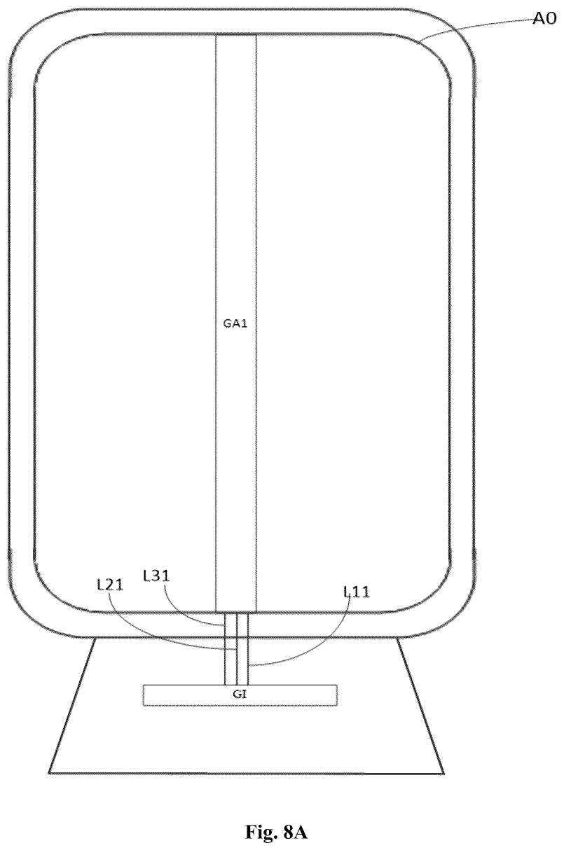

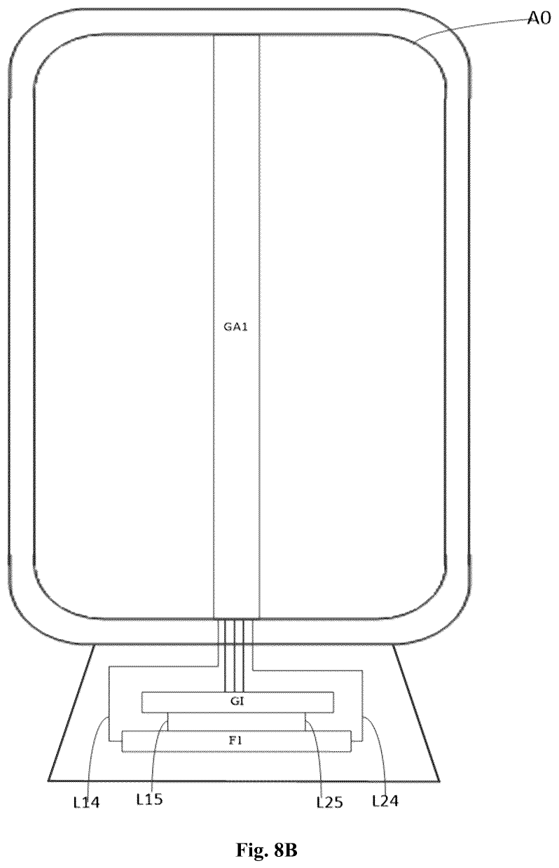

As shown in FIG. 8A, reference numeral P1 denotes a display panel, reference numeral A0 denotes a display area, and reference numeral GA1 denotes a first drive module; the first drive circuits in the first drive module GA1 are all the drive circuits included in the drive modules in the display panel.

GA1 is arranged in the middle of the display area A0.

The GA1 is electrically connected to the drive IC GI via a first first GOA signal line L11 extending in a vertical direction; the first first GOA signal line L11 is directly electrically connected to a port arranged in the middle of the drive IC GI.

The GA1 is electrically connected to the drive IC GI via a second first GOA signal line L21 extending in the vertical direction; the second first GOA signal line L21 is directly electrically connected to a port arranged in the middle of the drive IC GI.

The GA1 is electrically connected to the drive IC GI via a third first GOA signal line L31 extending in the vertical direction; the third first GOA signal line L31 is directly electrically connected to a port arranged in the middle of the drive IC GI.

Optionally, the GOA control signal may include a clock signal, a start signal, and a strobe signal.

The drive IC GI provides a clock signal to the first drive module GA1 via the first first GOA signal line L11.

The drive IC GI provides a start signal to the first drive module GA1 via the second first GOA signal line L21.

The drive IC GI provides a gating signal to the first drive module GA1 via the third first GOA signal line L31.

As shown in FIG. 8B, the display panel according to at least one embodiment of the present disclosure may further include a circuit board F1.

The circuit board F1 is arranged on a side of the drive IC GI away from the display area A0.

In FIG. 8B, reference numeral L14 is a first DC signal transmission line, reference numeral L24 is a second DC signal transmission line, reference numeral L15 is a third DC signal transmission line, and reference numeral L25 is a fourth DC signal transmission line.

The circuit board F1 provides a DC voltage signal to the GA12 via L14, to the GA22 via L24, and to the GI via L15 and L25.

In at least one embodiment shown in FIG. 8B, the drive IC GI is configured to generate a drive control signal according to the DC voltage signal, and provide the drive control signal to the first drive module GA1.

Both the drive IC GI and the circuit board F1 are arranged in the lower pad area.

At least one embodiment of the drive circuit is shown in FIGS. 8A and 8B of the present disclosure place all the drive circuits in the middle position of the display area A0, and are arranged below the anode layer; the GOA signal lines are instead introduced above the middle section of the drive IC GI, and the space of the middle section of the drive IC GI is fully used; and at least one embodiment of the drive circuit shown in FIGS. 8A and 8B of the present disclosure can reduce the size of the lower pad area and the winding length of the GOA signal lines so that the load of each GOA signal line is minimal and no difference. As far as possible, the GOA signal line uses a film layer which has no interference with other units in the current area, and other unit designs can further be modified in combination with the GOA signal line.

A display device according to an embodiment of the present disclosure includes the above-described display panel.

While the foregoing is directed to the preferred embodiments of the present disclosure, it will be understood by those skilled in the art that various changes may be made and equivalents may be substituted for elements thereof without departing from the spirit and scope of the present disclosure.

1. A display panel, comprising a display area and pixel circuits arranged in the display area, wherein the display panel further comprises a drive module and a drive integrated circuit (IC); the drive module comprises a plurality of drive circuits, and the drive circuits are configured to provide drive signals for the pixel circuits; the drive IC is configured to provide drive control signals for the drive circuits via gate on array (GOA) signal lines; the GOA signal lines comprise first GOA signal lines arranged between the display area and the drive IC;
at least part of the drive circuits comprised in the drive module are arranged in the display area;
the at least part of the drive circuits arranged in the display area and comprised in the drive module is electrically connected to the drive IC via the first GOA signal lines, for receiving the drive control signals from the drive IC;
the first GOA signal lines extend in a first direction; and
the display panel further comprises data lines, and the data lines are configured to provide data voltage for the pixel circuits; the data lines extend in substantially a same direction as the first direction.

2. The display panel according to claim 1, wherein the at least part of the drive circuits comprised in the drive module are arranged in the middle of the display area, and the at least part of the drive circuits are aligned in the first direction.

3. The display panel according to claim 1, wherein the at least part of the drive circuits comprised in the drive module are first drive circuits;
a plurality of drive circuits other than the first drive circuits comprised in the drive module are second drive circuits;
the drive IC and the first GOA signal lines are arranged on a first side of the display area; and
a plurality of second drive circuits comprised in the drive circuits are arranged on a second side and/or a third side of the display area; the second side and the third side are opposite sides.

4. The display panel according to claim 3, wherein the GOA signal lines further comprise second GOA signal lines extending in a second direction; the first direction intersects the second direction;
the first GOA signal lines are electrically connected to the second GOA signal lines;
the second GOA signal lines are electrically connected to the drive IC; and
the second GOA signal lines are configured to receive and pass the drive control signals from the drive IC.

5. The display panel according to claim 4, wherein a fan-out area, a bending area, a box-forming testing area, and an area where the drive IC is arranged are sequentially arranged at the first side of the display area in a direction away from the display area; and
the second GOA signal lines are arranged between the bending area and the box-forming testing area.

6. The display panel according to claim 3, wherein at least part of the first GOA signal lines are directly electrically connected to the drive IC, for receiving the drive control signals from the drive IC.

7. The display panel according to claim 6, wherein the GOA signal lines further comprise second GOA signal lines extending in a second direction; the first direction intersects the second direction;
part of the first GOA signal lines are electrically connected to the second GOA signal lines; and
the second GOA signal lines are directly electrically connected to the second drive circuits, for providing the drive control signals to the second drive circuits.

8. The display panel according to claim 1, wherein the first GOA signal lines are electrically connected to a port located in the middle of the drive IC.

9. The display panel according to claim 3, wherein the GOA signal lines further comprise second GOA signal lines, the second GOA signal lines extending in a second direction;
the first direction intersects the second direction;
the first GOA signal lines are directly connected to the second GOA signal lines;
a fan-out area, a bending area, a box-forming testing area, and an area where the drive IC is arranged are sequentially arranged at the first side of the display area in a direction away from the display area;
the second GOA signal lines are arranged in the fan-out area; and
the second GOA signal lines are electrically connected to the drive IC.

10. The display panel according to claim 4, wherein the plurality of second drive circuits are arranged on the second side and the third side of the display area;
a first end portion of the second GOA signal line is electrically connected to a second drive circuit arranged on the second side of the display area and a first port of the drive IC; and
a second end portion of the second GOA signal line is electrically connected to a second drive circuit arranged on the third side of the display area and a second port of the drive IC.

11. The display panel according to claim 4, wherein the plurality of second drive circuits are arranged on the second side of the display area; a first end portion of the second GOA signal line is electrically connected to a second drive circuit arranged on the second side of the display area and a first port of the drive IC; or,
the plurality of second drive circuits are arranged on the third side of the display area;
a second end portion of the second GOA signal line is electrically connected to a drive circuit arranged on the third side of the display area and a second port of the drive IC.

12. The display panel according to claim 3, further comprising a circuit board, wherein
the circuit board is arranged on a side of the drive IC away from the display area; and
the circuit board is electrically connected to the first drive circuit and the second drive circuit, for providing direct current (DC) voltage signals to the first drive circuit and the second drive circuit.

13. The display panel according to claim 12, wherein the circuit board is further electrically connected to the drive IC, for providing DC voltage signals to the drive IC; and
the drive IC is configured to generate the drive control signals according to the DC voltage signals, and provide the drive control signals to the first drive circuit and the second drive circuit.

14. The display panel according to claim 1, wherein all the drive circuits comprised in the drive module are arranged in the display area; and
the first GOA signal lines are directly electrically connected to the drive IC, for receiving the drive control signals from the drive IC.

15. The display panel according to claim 14, further comprising voltage signal lines, wherein
the voltage signal lines are electrically connected to the drive circuits, for providing DC voltage signals to the drive circuits.

16. The display panel according to claim 15, wherein
the voltage signal lines are electrically connected to the drive IC for providing DC voltage signals to the drive IC; and
the drive IC is configured to generate the drive control signals according to the DC voltage signals, and provide the drive control signals to the drive circuits.

17. The display panel according to claim 16, further comprising a circuit board arranged on the drive IC away from the display area; and
the circuit board is electrically connected to the voltage signal lines, for providing the DC voltage signals to the voltage signal lines.

18. A display device, comprising the display panel according to claim 1.
